(19) United States
(12) Patent Application Publication
(10) Pub. No.: US 2006/0289853 A1
(43) Pub. Date: Dec. 28, 2006

(54) Apparatus for manufacturing a quantum-dot element

(75) Inventors: Hsueh-Shih Chen, Hsinchu City (TW); Dai-Luon Lo, Dahu Township (TW); Gwo-Yang Chang, Jiali Township (TW); Chien-Ming Chen, Yangmei Township (TW)

Correspondence Address: BACON & THOMAS, PLLC, 625 SLATERS LANE, FOURTH FLOOR, ALEXANDRIA, VA, 22314, US

(73) Assignee: Industrial Technology Research Institute, Hsinchu (TW)

(21) Appl. No.: 11/187,828

(22) Filed: Jul. 25, 2005

(30) Foreign Application Priority Data
Aug. 23, 2004 (TW) 093125331

(51) Int. Cl. H01L 31/00

(52) U.S. Cl. 257/14

(57) ABSTRACT

An apparatus for manufacturing a quantum-dot element is disclosed. The apparatus includes a reaction chamber for evaporating or sputtering at least one electrode layer or at least one buffer layer on the substrate. The substrate-supporting base is located inside the reaction chamber for fixing the substrate. The atomizer has a gas inlet and a sample inlet. More specifically, the gas inlet and the sample inlet feed the atomizer respectively with a gas and a precursor solution having a plurality of functionalized quantum dots, and thereby form a quantum-dot layer on the substrate. The apparatus of the present invention can form a quantum dot layer with uniformly distributed quantum dots and integrate the processes for forming a quantum-dot layer, a buffer layer, and an electrode layer together at the same chamber. Therefore, the quality of produced element can be substantially improved.

### BACKGROUND OF INVENTION

1. Field of Invention

The present invention relates to an apparatus for manufacturing a quantum-dot element and, more particularly, to an apparatus for manufacturing a photoelectric element with colloidal quantum dots.

2. Description of Related Art

Recently, the hybrid of organic or inorganic materials has become the emphasis of the development in photoelectric materials. On the other hand, the nano-particulate obtained by liquid or gaseous synthesis is also the focus of the development in material technology. Although the nano-particulate as well as the composite of the nano-particulate and the organic molecule inherently have good material property, they become deteriorated when being applied to the photoelectric devices. The main problem lies in that the manufacturing process of the nano-particulate is not compatible with the vacuum process for manufacturing the photoelectric element and, therefore, the manufacturing of the photoelectric element with the nano-particulates can not be carried out in a continuous process.

Generally, the quantum dot of the quantum-dot element is formed by either a vacuum process or chemical synthesis. The vacuum process further includes the Molecular Beam Epitaxy (MBE) method, the Chemical Vapor Deposition (CVD) method, and the Ultrahigh Vacuum Physical Vapor Deposition (UHVPVD) method. However, the quantum dots formed by these vacuum processes usually have too large particle sizes (usually larger than 10 nm) and too low densities. Also, the particle sizes are not uniform enough. Therefore, the quantum dots formed by the vacuum process are unsuitable for manufacturing device with large superficial content. As for the chemical synthesis, it can produce quantum dots with well-distributed size, which generally ranges from 1 nm to 10 nm. In addition, the quantum dots formed by the chemical synthesis have a higher density, so they can be used to manufacture devices with large superficial content. The quantum-dot layer formed by the conventional chemical synthesis is shown as FIGS. 1a to 1c. First, the particles 10 and the organic molecules 20 are mixed in an atmosphere of inert gas, which prevents the particles 10 from oxidizing. Namely, the quantum dots are dispersed in the organic solvent, as shown in FIG. 1a. Afterwards, the quantum dots in the organic solvent are deposited onto the substrate 30 by spin coating in the grove box, as shown in FIG. 1b. Subsequently, the substrate 30 is put into the vacuum evaporation chamber or the sputtering chamber for depositing a carrier transport film or an electrode 40, as shown in FIG. 1c. However, the quantum dots may easily aggregate in the aforesaid process, as shown in FIG. 2c. Besides, the product is easily contaminated during the mixing or the spin coating step, and consequently suffers from quality deterioration. Moreover, the product might be damaged when it is transported between different manufacturing apparatuses. In addition to the above-mentioned method, the quantum dots may also be adsorbed onto the substrate by dipping. However, although a uniform layer of quantum dots can be formed, the solvent might easily contaminate other parts of the quantum-dot element such as the carrier transport layer or the electrode.

In order to overcome the imperfection of such a non-continuous process, the apparatus for manufacturing a quantum-dot element of the present invention combines the conventional aerosol spraying process with the vacuum process. In particular, the aerosol spraying process is used for introducing the solid powders. Therefore, the organic-inorganic composite element can be manufactured in a single chamber, and the bottleneck of deterioration in material quality can be substantially improved.

### SUMMARY OF THE INVENTION

The object of the present invention is to provide an apparatus for manufacturing a quantum-dot element so that the electrode layer, the emitting material layer, and the carrier transport layer of the quantum-dot element can all be formed in the same apparatus, and thus the quality loss due to transferring between different apparatuses can be substantially avoided. Furthermore, the quantum dots can be distributed uniformly, the sizes of quantum dots can lie in the nano-order, and the performance of the quantum-dot element in light, electricity, and magnetism can be improved.

In order to achieve the above object, the apparatus for manufacturing a quantum-dot element having a quantum-dot layer formed on a substrate, comprises a reaction chamber, a substrate-supporting base, and an atomizer. The reaction chamber provides a reaction condition for evaporating or sputtering at least one electrode layer or at least one buffer layer on the substrate. The substrate-supporting base is located inside the reaction chamber for fixing the substrate. The atomizer has a gas inlet and a sample inlet. Moreover, the sample inlet feeds the atomizer with a precursor solution having a plurality of functionalized quantum dots, and thereby forms a quantum-dot layer on the substrate.

The apparatus for manufacturing a quantum-dot element of the present invention can produce devices having the functionalized quantum dots, for example, a light-emitting diode, a laser diode, a detective device such as a light sensor or chemical sensor, photonic crystals, light modulators, magnetic thin film, or a battery using solar energy.

Generally, the quantum-dot element is constructed of a bottom electrode layer, a buffer layer, a quantum-dot layer, another buffer layer, and a top electrode layer formed on a substrate. The buffer layer is usually composed of at least one carrier injection/exportation layer pair, and can also be omitted optionally. Furthermore, the substrate can be selected according to the function of the resultant element, and can be an ITO glass substrate, a silicon substrate, an Al₂O₃ substrate, or a GaAs substrate.

When the apparatus of the present invention is used, the substrate with or without the bottom electrode layer is fixed on the substrate-supporting base in the deposition chamber first. Subsequently, the buffer layer or the electrode layer is formed by a vacuum deposition process, for example, a Chemical Vapor Deposition (CVD) process, or a Physical Vapor Deposition (PVD) process such as evaporation or sputtering. Therefore, the deposition chamber could be a CVD chamber, an evaporation chamber, or a sputtering chamber. Afterwards, a precursor solution is prepared by considering the size of the droplet sprayed out from the atomizer, the property of the solvent, and the volume of the functionalized quantum dot. Owing to the functionalized group, the quantum dots can be dispersed in the solvent uniformly. Thereafter, the precursor solution is sprayed onto the surface of the substrate by the atomizer to form a quantum-dot layer. Moreover, the quantum dot can be a metal quantum dot, a semiconductor quantum dot, a magnetic quantum dot, an organic molecule quantum dot, or a polymer quantum dot. In addition, the diameter of the quantum dot formed by the present invention is less than 100 nm, and preferably ranges from several nano-meters to tens of nano-meters. The dispersion medium of the quantum dots, i.e. the solvent, can be water, an aqueous solution containing a surfactant, a polar organic solvent such as methanol, a non-polar organic solvent such as toluene, or a polymer solvent such as a diluted solution of a conjugate polymer, an epoxy resin, polymethylmethacrylate, polycarbonate, or a cyclic olefin co-polymer. The type of the atomizer is not restricted, and can be the conventional atomizer that sprays droplets by mixing and pressurizing the gas with the solution, or the supersonic atomizer that produces droplets by using the vibration energy of the piezoelectric ceramics. Besides, the substrate-supporting base is preferably a rotary plate that can drive the substrate to rotate and heat the substrate. More preferably, the substrate support base can adjust the rotation speed and the temperature of the substrate. Preferably, one shutter is mounted between the substrate supporting base and the atomizer, and the other shutter is mounted between the substrate supporting base and the evaporation or sputtering source for preventing the unstable evaporation or sputtering source from depositing on the substrate at the beginning of the heating of the evaporation or sputtering source. Similarly, at the initial stage of the spraying of the precursor solution, the droplets are not uniform enough. Therefore, the shutter is also used for blocking the non-uniform droplets from arriving at the substrate.

The preparation of precursor solution is quite important in the present invention. In addition to the functionalization that facilitates the uniform dispersion of the quantum dots, the concentration of the precursor solution should also be calculated precisely. More specifically, the concentration of the precursor solution is calculated first in order to produce droplets containing a predetermined number of quantum dots. Afterwards, a proper amount of quantum-dot powder is dispersed in the solvent to prepare the precursor solution with a predetermined concentration.

For example, the average diameter of the functionalized quantum-dot powder is 20 nm, and the average diameter of the droplet sprayed from the atomizer is 100 nm. If each droplet is predetermined to contain only one quantum-dot powder, then the volume concentration of the precursor solution can be calculated as the following equation (1):
(20 nm)³/{(100 nm)³+(20 nm)³}=4.63×10⁻³=0.463V % (1)

If each droplet is predetermined to contain fifteen quantum-dot powders, then the volume concentration of the precursor solution can be calculated as the following equation (2):
[15×(20 nm)³]/[(100 nm)³+15×(20 nm)³]=0.1071=10.71V % (2)

If for a pair of droplets, only one contains a quantum-dot particle and the other does not, then the volume concentration of the precursor solution will be half the concentration of equation (1).

### BRIEF DESCRIPTION OF THE DRAWINGS

FIGS. 1a˜1c are schematic views showing the formation of the quantum-dot layer by the chemical synthesis of prior art;

FIG. 2a is an SEM picture showing the distribution of quantum dots in the quantum-dot layer of prior art;

FIG. 2b is an SEM picture showing the distribution of quantum dots in the quantum-dot layer formed by the present invention;

FIG. 3 is a schematic view showing the structure of the light-emitting element having a ZnSe quantum-dot layer formed by the present invention;

FIG. 4 is a schematic view showing the first preferred embodiment of the apparatus for manufacturing the quantum-dot element of the present invention;

FIG. 5 is a schematic view showing the second preferred embodiment of the apparatus for manufacturing the quantum-dot element of the present invention;

FIG. 6 is a schematic view showing the third preferred embodiment of the apparatus for manufacturing the quantum-dot element of the present invention;

FIG. 7 is a schematic view showing the fourth preferred embodiment of the apparatus for manufacturing the quantum-dot element of the present invention;

FIG. 8 is a schematic view showing the fifth preferred embodiment of the apparatus for manufacturing the quantum-dot element of the present invention;

FIG. 9a is a figure showing the relationship between the brightness and the voltage of the light-emitting element manufactured by the present invention; and

FIG. 9b is a figure showing the relationship between the brightness and the voltage of the light-emitting element manufactured by the prior art.

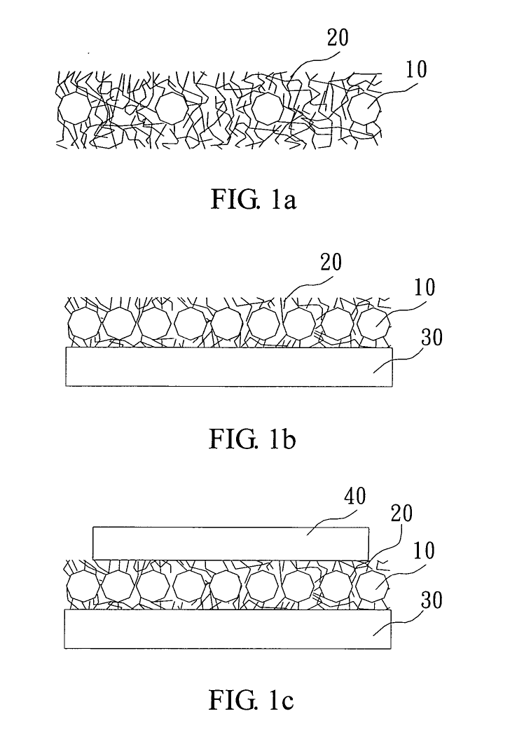

### DETAILED DESCRIPTION OF THE PREFERRED EMBODIMENTS

### Embodiment 1

### Preparation of the Precursor Solution Containing CdSe/ZnS Quantum Dot with a Diameter of 3 nm

A piezoelectric atomizer that forms toluene droplets with an average diameter of 1000 nm introduces the precursor solution. If the influence to the diameter of the droplet caused by the CdSe/ZnS quantum dot is neglected and if each droplet is predetermined to have one quantum-dot particle, then the volume concentration of the precursor solution can be calculated as the following equation (3):
(3 nm)³/{(1000 nm)³+(3 nm)³}=9.00×10⁻⁹ (3)

If each droplet is predetermined to have three quantum-dot particles, then the desired concentration will be three times the concentration obtained from equation (3). Similarly, if each pair of droplets has only one quantum-dot particle, then the desired concentration will be half the concentration obtained from equation (3).

### Embodiment 2

### Preparation of the Precursor Solution Containing ZnO Particle with a Diameter of 1 μm

The precursor solution is introduced by a conventional atomizer to form water droplets with an average diameter of 15 μm. If the influence to the diameter of the droplet caused by the ZnO particle is neglected and if each droplet is predetermined to have one particle, then the volume concentration of the precursor solution can be calculated as the following equation (4):
(1 μm)³/{(15 μm)³+(1 μm)³}=2.96×10 (4)

The volume concentration calculated from equation (4) equals to a weight concentration of 1.62×10⁻³.

If each droplet is predetermined to have five particles, then the desired concentration will be five times the concentration obtained from equation (4). Similarly, if each pair of droplets contains only one particle, then the desired concentration will be half the concentration obtained from equation (4).

### Embodiment 3

### Preparation of the Precursor Solution Containing Silica Nano-Particle with a Diameter of 20 nm

The precursor solution is introduced by a piezoelectric atomizer to form water droplets with an average diameter of 100 nm. If the influence to the diameter of the droplet caused by the silica particle is neglected and if each droplet is predetermined to have one particle, then the volume concentration of the precursor solution can be calculated as the following equation (5):
(20 nm)³/{(100 nm)³+(20 nm)³}=4.63×10⁻³=0.463V % (5)

If each droplet is predetermined to have fifteen particles, then the desired concentration will be fifteen times the concentration obtained from equation (5). Similarly, if each pair of droplets contains only one particle, then the desired concentration will be half the concentration obtained from equation (5).

### Embodiment 4

### Manufacturing of the Light-Emitting Element Having ZnSe Quantum Dots

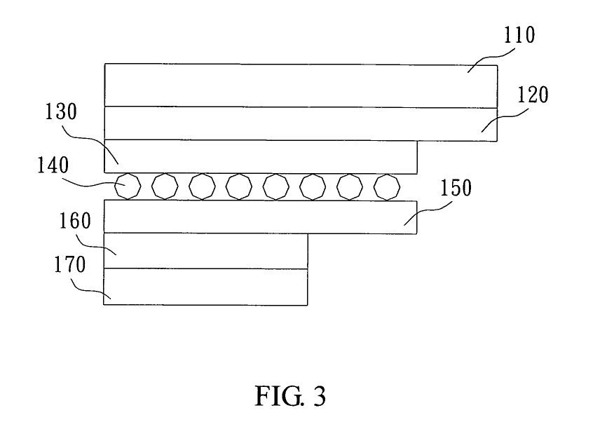

With reference to FIG. 3, there is shown a schematic view of the light-emitting element having ZnSe quantum dots according to the present invention. The light-emitting element includes a glass substrate 110, on which an anode layer 120 made of the conductive glass, a hole transport layer (HTL) 130, an emitting material layer (EML) 140 composed of CdSe quantum dots, an electron transport layer (ETL) 150, and a cathode layer 170 made of aluminum are formed sequentially. Moreover, there is usually a LiF layer 160 formed between the cathode layer 170 and the electron transport layer 150.

In the present embodiment, the EML, the HTL, and the ETL can be made of any conventional materials, which are listed in the following table:

| | Light- | | | | | |
|---|---|---|---|---|---|---|
| Material | Emitting | Green | Red | Yellow | Blue | White |
| Small | EML | Alq, DPT, | DCM-2, | Rubrene | TPAN, DPAN, | TTBND/ |
| molecule | | Alq₃, Bebq₂, | TMS-SiPc, | | DPAP, | BTX-1 |
| material | | DMQA, | DCJTB, | | Perylene(C₂₀H₁₂), | |
| | | Coumarin6, | ABTX | | DPVBi, PPD, | |
| | | Q, NMQ, | | | a-NPD₂, | |
| | | Quinacrine | | | b-NPD, | |
| | | | | | TTBND, | |
| | | | | | DCTA, TDAPTz | |

| | HTL | TPAC, TPD, a-NPD, 2Me-TPD, FTPD, Spiro-TPD(TAD), |
|---|---|---|
| | | t-TNATA, OTPAC, CuPc, TPTE, m-MTDATA |
| | ETL | Alq₃, Bebq₂, BND, OXD, ZnPBT, PBD, TAZ |
| Polymer | EML | PPV, PF, MEH-PPV |
| material | | |
| | HTL | PEDOT, PAni, PVK, PTPDES |

Wherein the above abbreviations are defined as follows:
NPB: N,N′-di(naphthalen-1-yl)-N,N′-di(phenyl)benzidin,
α-NPB: N,N′-Bis(naphthalen-1-yl)-N,N′-bis(phenyl)benzidine,
DMFL-NPB: N,N′-di(naphthalen-1-yl)-N,N′-di(phenyl)-9,9-dimethyl-fluorene,
TPD: N,N′-Bis-(3-methylphenyl)-N,N′-bis-(phenyl)-benzidine,
Spiro-TPD: N,N′-bis-(3-methylphenyl)-N,N′-bis-(phenyl)-spiro,
DMFL-TPD: N,N′-bis(3-methylphenyll)-N,N′-bis(phenyl)-9,9-diphenyl-fluorene,
Spiro-NPB: N,N′-di(naphthalen-1-yl)-N,N′-diphenyl-spiro),
TCP: 1,3,5-tris(carbazol-9-yl)-benzene,
TNB: N,N,N′,N′-tetrakis(naphth-1-yl)-benzidine,
MCP: 1,3-bis(carbazol-9-yl)-benzene,
PVK: poly (N-vinyl carbazole),
PEDOT: poly (ethylenedioxythiophene,
PSS: poly (styrene sulfonic acid),
MEH-PPV: Poly(2-mthoxy-5-(2′-ethylhexyloxy)-1,4-phenylenevinylene),
MEH-BP-PPV: Poly[2-Methoxy-5-(2′-ethylhexyloxy)-1,4-phenylenevinylene-co-4,4′-bisphenylenevinylene],
PF-BV-MEH: Poly[(9,9-dioctylfluoren-2,7-diyl)-co-(1,4-diphenylene-vinylene-2-methoxy-5-{2-ethylhexyloxy}benzene)],
PF-DMOP: Poly[(9,9-dioctylfluoren-2,7-diyl)-co-(2,5-dimethoxybenzen-1,4-diyl)],
PFH: Poly[(9,9-dihexylfluoren-2,7-diyl)-alt-co-(benzen-1,4-diyl)],
PFH-EC: Poly[(9,9-dihexylfluoren-2,7-diyl)-co-(9-ethylcarbazol-2,7-diyl)],
PFH-MEH: Poly[(9,9-dihexylfluoren-2,7-diyl)-alt-co-(2-methoxy-5-{2-ethylhexyloxy}phenylen-1,4-diyl)],
PFO: Poly[(9,9-dioctylfluoren-2,7-diyl),
PF-PPV: Poly[(9,9-di-n-octylfluoren-2,7-diyl)-co-(1,4-vinylenephenylene)],
PF-PH: Poly[(9,9-dihexylfluoren-2,7-diyl)-alt-co-(benzen-1,4-diyl)],
PF-SP: Poly[(9,9-dihexylfluoren-2,7-diyl)-alt-co-(9,9′-spirobifluoren-2,7-diyl)],
Poly-TPD: Poly(N,N′-bis(4-butylphenyl)-N,N′-bis(phenyl)benzidine,
Poly-TPD-POSS: Poly(N,N′-bis(4-butylphenyl)-N,N′-bis(phenyl)benzidine,
TAB-PFH: Poly[(9,9-dihexylfluoren-2,7-diyl)-co-(N,N′-di(4-butylphenyl)-N,N′-diphenyl-4,4′-diyl-1,4-diaminobenzene)],
PPB: N,N′-Bis(phenanthren-9-yl)-N,N′-diphenylbenzidine,
Alq₃: Tris-(8-hydroxyquinoline) aluminum,
BAlq₃: (Bis-(2-methyl-8-quinolinolate)-4-(phenylphenolato)-alumium),
BCP: 2,9-Dimethyl-4,7-diphenyl-1,10-phenanthroline,
CBP: 4,4′-Bis(carbazol-9-yl)biphenyl,
TAZ: 3-(4-Biphenylyl)-4-phenyl-5-tert-butylphenyl-1,2,4-triazole

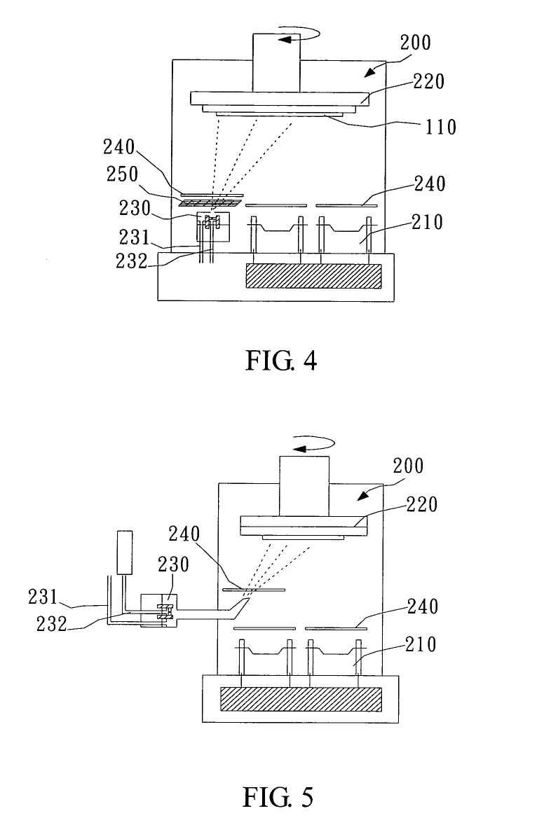

In the present embodiment, the apparatus for manufacturing the quantum-dot element is shown in FIG. 4. An evaporation chamber 200 having a plurality of evaporation sources 210 is used to deposit the hole transport layer, the quantum-dot emitting layer, and the electron transport layer successively on the substrate 110. A substrate-supporting base 220 is located in the evaporation chamber 200 for fixing the substrate 110. In addition, an atomizer 230 is used to pressurize the mixture of a gas and a solution. More specifically, nitrogen and a toluene solution containing functionalized CdSe quantum dots are sprayed into the evaporation chamber 200 for generating droplets containing quantum dots. The nitrogen and the toluene solution are fed respectively through a gas inlet 231 and a sample inlet 232, both of which are connected with the atomizer 230. Furthermore, several shutters 240 are mounted between the substrate-supporting base and the atomizer 230, as well as between the substrate supporting base and the evaporation sources 210. Owing to the shutters 240, the atomizer 230 and the evaporation sources 210 can be switched and prevented from contaminating with each other. Preferably, a sieve 250 is mounted between the atomizer 230 and the shutter 240 for controlling the size of droplets that deposit on the substrate 110. Besides, the atomizer 230 is disposed at the bottom of the chamber 200, and the substrate-supporting base 220 is located at the top of the chamber 200. Hence, the droplets transported upwardly can deposit uniformly on the substrate and form a quantum-dot layer with uniform distribution of quantum dots.

The substrate-supporting base 220 is a rotary plate that drives the substrate to rotate. Also, the substrate-supporting base 220 can heat the substrate so as to increase the uniformity of the hole transport layer and electron transport layer formed by evaporation, as well as the quantum-dot emitting layer formed by atomization. In addition, the solvent on the substrate can be driven out accordingly. The evaporated material includes an organic molecule, an organic metal, an organic semiconductor, a metal, a semiconductor, a hole or electron transport material, and a super conductive material. In particular, the organic molecule contains the small organic molecule that has a molecular weight less than 100,000, and an organic polymer. The organic metal is a molecule having metal and an organic group such as C—R, O—R, N—R, or S—R group, wherein R represents an organic molecule. The organic semiconductor contains an organic compound that has an electrically conductive property and a light-emitting property, such as a conjugate polymer. The metal includes groups 1A, 2A, 3A, 4A, 5A, 6A, 7A, 8A, 1B, and 2B metals in the periodic table. The semiconductor contains the semiconductors of groups 4B and the compound semiconductors of groups 1B, 2B, 3B, 4B, 5B, 6B, and 7B. The hole or electron transport material includes the hole or electron transport materials used for the PLED and OLED. As for the super conductive material, it includes the compounds that have at least two of Y, Ba, Cu, and O elements and other superconductors.

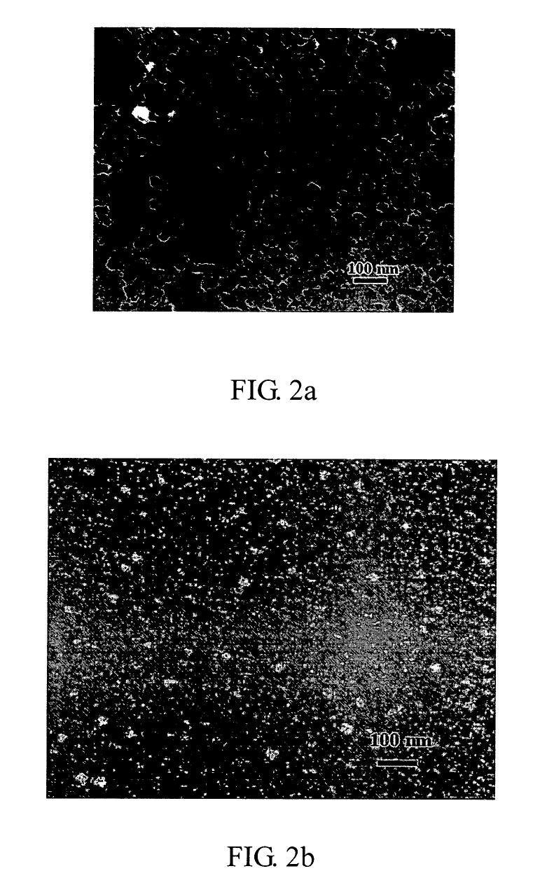

When the quantum-dot element is manufactured, the substrate 110 having the anode layer 120 made of the conductive glass is transferred into the evaporation chamber 200 and fixed on the substrate-supporting base 220 first. Simultaneously, the evaporation source 210 is turned on under vacuum condition to form a hole transport layer 130 on the substrate 110. Afterwards, a high-pressure gas is used to spray out the droplets containing functionalized quantum dots through the atomizer 230. Subsequently, the evaporation source 210 of the electron transport layer 150 is turned on to form the electron transport layer 150 on the glass substrate 110. Finally, the glass substrate 110 is transferred out of the chamber, and then sent to other apparatus for depositing the cathode layer 170. At this point, the manufacture of the light-emitting element is finished. The distribution of quantum dots in the quantum-dot emitting layer 140 can be as shown as FIG. 2b.

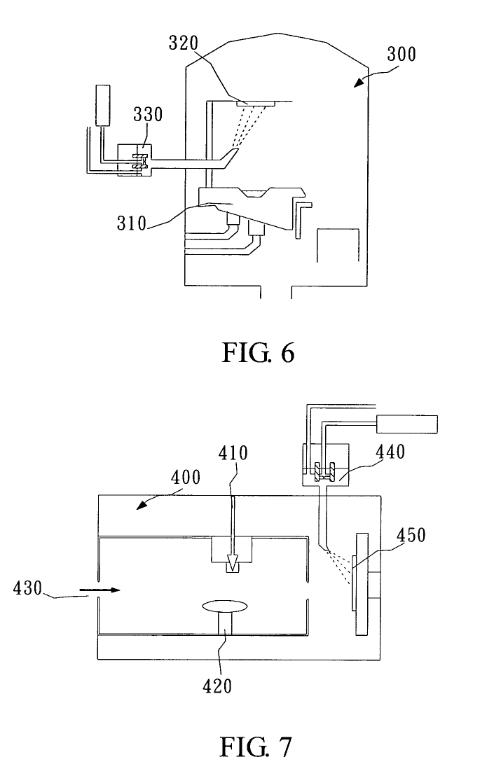

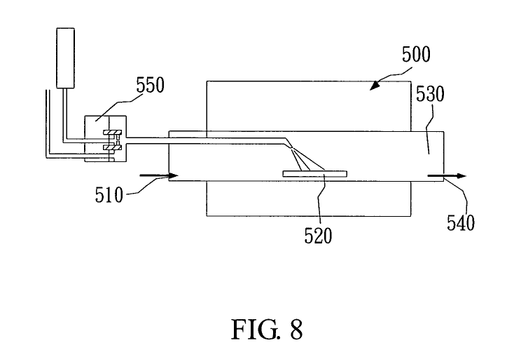

The atomizer 230, the gas inlet 231, and the sample inlet 232 are mounted inside the chamber 200 in the present embodiment. Also, those parts can be mounted outside of the chamber 200 except the spray head of the atomizer 230, as shown in FIG. 5. In this preferred embodiment, the crucible is used to serve as the evaporation source, which is melted by the thermal resistance materials such as a tungsten line or a tantalum line. However, the deposition chamber 300 can also use an electron-beam gun 310 to melt the evaporation source, and an externally connected removable atomizer 330 to deposit a thin film on the substrate 320, as shown in FIG. 6. Alternatively, with reference to FIG. 7, the laser 410 can be used to gasify the target 420 in the chamber 400, and the gas 430 can transfer the gasified target material to form the electrode layer or the buffer layer on the substrate 450. Also, a removable atomizer 440 is externally connected to form the quantum-dot layer on the substrate 450. Furthermore, in the quartz tube 530 of the chamber 500, a film is formed on the substrate 520 by the Chemical Vapor Deposition process, as shown in FIG. 8. More particularly, the feed inlet 510 is located at one end of the quartz tube 530, and at the other end of the quartz tube 530, there is an outlet 540 connecting with a pump. The outlet 540 can generate a pressure difference in the quartz tube 530. Thus, the pressure difference drives the gas to flow and form a film on the substrate 520. Similarly, the atomizer 550 serves to form the quantum dots in the film.

In the present invention, the carrier transport layer can be deposited optionally before or after the quantum-dot layer is formed. Alternatively, the carrier transport layer and the quantum-dot layer can be formed by turns. Finally, the electrode can also be deposited in the same chamber. As the above-mentioned steps are all carried out in the vacuum chamber, they can be accomplished in a continuous process. Consequently, the manufacturing time and cost are reduced. Besides, the product is effectively prevented from being contaminated. Moreover, the quantum dots can be distributed uniformly on the substrate due to the spraying of the atomizer. The size of the quantum dots can be reduced to nano-meter level successfully.

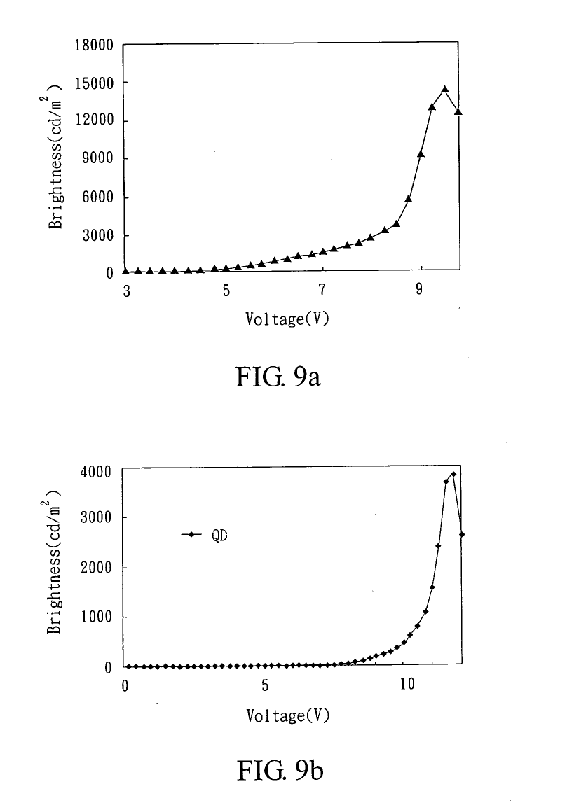

The relationship between the brightness and the exerted voltage of the emitting element having ZnSe quantum dots formed by the present invention is compared with that of the conventional emitting element, of which the quantum-dot layer is formed by coating. As shown in FIG. 9a, the brightness of the emitting element manufactured by the present invention reaches 10,000 lumens as the voltage is 9V. However, the brightness of the conventional emitting element is less than 1,000 lumens as the voltage is 9V, as shown in FIG. 9b. Therefore, the emitting element manufactured by the apparatus of the present invention exhibits a substantially improved light-emitting efficiency.

The above detailed descriptions are given by way of example and not intended to limit the invention solely to the embodiments described herein.

What is claimed is:

1. An apparatus for manufacturing a quantum-dot element having a quantum-dot layer formed on a substrate, comprising:
a reaction chamber for evaporating or sputtering at least one electrode layer or at least one buffer layer on the substrate;
a substrate supporting base located inside the reaction chamber for fixing the substrate; and
at least one atomizer having a gas inlet and a sample inlet, wherein the gas inlet and the sample inlet feed the atomizer respectively with a gas and a precursor solution having a plurality of functionalized quantum dots, and thereby forms a quantum-dot layer, of which the quantum dot has a diameter less than 100 nm on the substrate.

2. The apparatus as claimed in claim 1, wherein the volume concentration of the precursor solution equals the volume of the quantum dot divided by the average volume of the droplets sprayed by the atomizer, and ranges from 0% to 99%.

3. The apparatus as claimed in claim 1, wherein the substrate is a glass substrate, a silicon substrate, an Al₂O₃ substrate, or a GaAs substrate.

4. The apparatus as claimed in claim 1, wherein the buffer layer is a metal film, a semiconductor film, or an organic film.

5. The apparatus as claimed in claim 1, wherein the quantum dot is selected from a group consisting of a metal quantum dot, a semiconductor quantum dot, a magnetic quantum dot, a small organic molecule quantum dot, and a polymer quantum dot.

6. The apparatus as claimed in claim 1, wherein the precursor solution has a solvent selected from the group consisting of water, an aqueous solution containing a surfactant, a polar organic solvent, a non-polar organic solvent, and a polymer solvent.

7. The apparatus as claimed in claim 1, wherein the gas is an inert gas or nitrogen gas.

8. The apparatus as claimed in claim 1, wherein the atomizer mixes and pressurizes the gas and the precursor solution to spray out the droplets of the precursor solution.

9. The apparatus as claimed in claim 1, wherein the atomizer is a supersonic atomizer for producing the droplets containing the quantum dots.

10. The apparatus as claimed in claim 1, wherein the substrate-supporting base is a rotary plate that drives the substrate to rotate.

11. The apparatus as claimed in claim 1 further comprising a shutter located between the substrate supporting base and the atomizer and acting as the switch of the atomizer.

12. The apparatus as claimed in claim 1 further comprising a sieve located between the atomizer and the shutter for controlling the size of the droplets arriving at the substrate.

13. The apparatus as claimed in claim 1, wherein the atomizer is located at the bottom of the reaction chamber and the substrate-supporting base is located at the top of the reaction chamber for delivering the droplets upward to the substrate.

14. The apparatus as claimed in claim 1, wherein the buffer layer is a carrier transport layer, a carrier injection layer, or the combination thereof.
